(19) United States
(12) Patent Application Publication
(10) Pub. No.: US 2005/0046458 A1
(43) Pub. Date: Mar. 3, 2005

(54) Digital delay elements constructed in a programmable logic device

(76) Inventors: Charles G. Schroeder, Round Rock, TX (US); Daniel J. Baker, Austin, TX (US); Glen O. Sescila III, Pflugerville, TX (US)

Correspondence Address: Jeffrey C. Hood;Meyertons, Hood, Kivlin, Kowert & Goetzel PC, P.O. Box 398, Austin, TX, 78767, US

(21) Appl. No.: 10/651,124

(22) Filed: Aug. 28, 2003

(51) Int. Cl. H03H 11/26

(52) U.S. Cl. 327/276

(57) ABSTRACT

A delay circuit. In one embodiment, a programmable logic device (PLD) is used to implement one or more delay circuits having a plurality of delay elements. Included in the plurality of elements are a balanced number of logic elements such that rising and falling edges of a signal passing through the delay circuit propagate with substantially the same amount of delay. The delay circuit may also include a selector circuit coupled to select an output from one of the plurality of delay elements. The delay circuit may be implemented such that it preserves the duty cycle and/or pulse width of signals to which the delay is applied.

### BACKGROUND OF THE INVENTION

1. Field of the Invention

This invention relates to digital circuits, and more particularly, the delay lines implemented in digital circuits.

2. Description of the Related Art

In complex digital systems, there often exists a need to adjust the phase delay of one or more signals. The phase delay of signals may need to be adjusted for clock and/or data alignment purposes, and may be necessary to ensure that data being transmitted or received is properly synchronized with a clock signal. For example, a plurality of signals transmitted in parallel on a bus may be required to arrive at a receiver at approximately the same time. Such timing is especially critical for digital systems that operate at high frequencies.

One common method of adjusting the phase delay of signals in a digital system is to use delay lines. Delay lines may be implemented as independent components. These independent components can consume valuable board area. Such delay line components may be expensive and have fixed functionality (e.g., the range and resolution of the delay is set by the vendor and is not configurable).

Given their expense, their lack of configurability, and the area consumed, traditional delay line components may not be suitable for many digital systems. For example, traditional delay line components may not be suitable for digital systems where cost and/or size are significant design constraints. However, despite these constraints, the need for delay lines may still exist for such systems.

### SUMMARY OF THE INVENTION

A delay circuit is disclosed. In one embodiment, a programmable logic device (PLD) is used to implement one or more delay circuits each having a plurality of delay elements. A balanced number of logic elements are included in the plurality of elements such that rising and falling edges of a signal passing through the delay circuit propagate with substantially the same amount of delay. The delay circuit may also include a selector circuit coupled to select an output from one of the plurality of delay elements. The delay circuit may be implemented such that it preserves the duty cycle and/or pulse width of signals to which the delay is applied.

In one embodiment, each of the one or more delay circuits includes delay elements having a large delay, delay elements having a medium delay, and delay elements having a fine delay. The large delay elements may include inverters and/or non-inverting buffers, and provide delay step sizes that are coarse with respect to the medium and fine delay elements. The medium delay elements may include an inverter or a non-inverting buffer, and provide a delay step size that is less than that of a large delay element but greater than that provided by a fine delay element. A fine delay element may include a plurality of wires of differing lengths and provides a delay that is less than that of large or medium delay elements. A delay circuit may be implemented by cascading one or more delay elements together, and may include large, medium, and fine delay elements. Using delay elements of various sizes, the delay circuit may be implemented such that it is linear and monotonic. Using the various delay element sizes may also allow the design of a delay circuit meeting specific range and resolution requirements.

As noted above, a PLD may be used to implement the delay circuit. In one embodiment, the PLD is a field programmable gate array (FPGA). Embodiments using any other type of PLD (e.g. programmable array logic, or PAL's) are possible and contemplated. In addition to implementing the delay circuit, the PLD may also be used to implement other functions which a PLD might be used for.

### BRIEF DESCRIPTION OF THE DRAWINGS

Other aspects of the invention will become apparent upon reading the following detailed description and upon reference to the accompanying drawings in which:

FIG. 1A is a block diagram of one embodiment of an exemplary system implementing delay lines using a programmable logic device (PLD);

FIG. 1B is a block diagram of one embodiment of a circuit implementing a digital delay line;

FIG. 1C is a block diagram of one embodiment of a circuit implementing a plurality of digital delay lines;

FIG. 1D is a block diagram of another embodiment of a circuit implementing a plurality of digital delay lines;

FIG. 2A is a block diagram of one embodiment of a delay element for implementing a large delay;

FIG. 2B is a block diagram of one embodiment of a delay element for implementing a medium delay;

FIG. 2C is a block diagram of one embodiment of a delay element for implementing a fine delay;

FIG. 3 is a block diagram of one embodiment of a delay line implemented using large delay elements, medium delay elements, and fine delay elements;

FIG. 4A is a drawing of one embodiment of a system used to program a PLD, wherein programming the PLD includes implementing delay circuits; and

FIG. 4B is a flow diagram of one embodiment of a method in which the delay circuits may be configured to provide a specified amount of delay.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling with the spirit and scope of the present invention as defined by the appended claims.

### DETAILED DESCRIPTION OF THE INVENTION

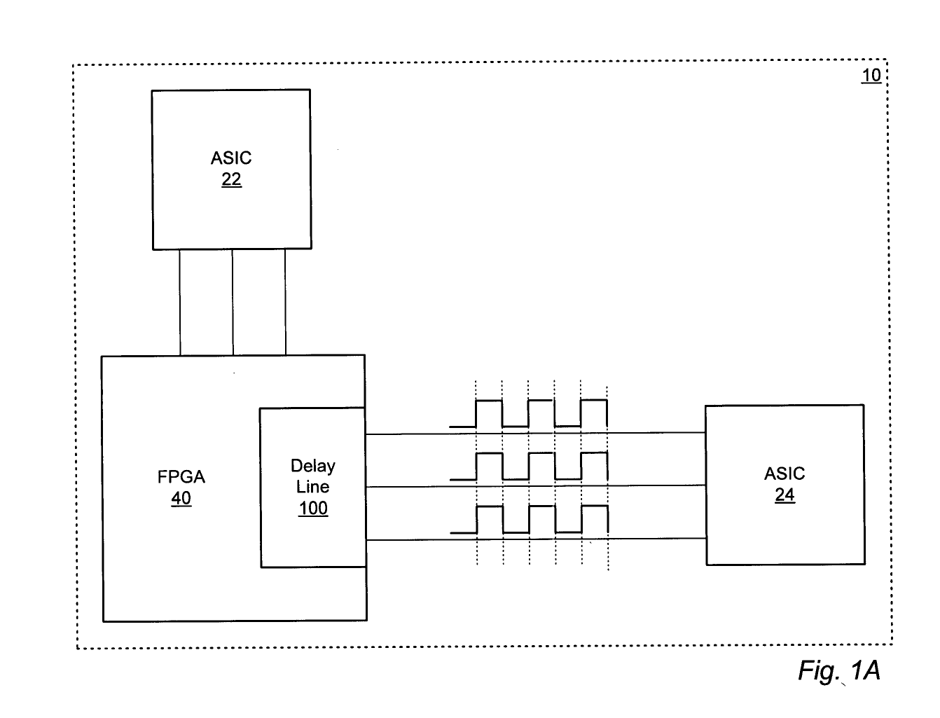

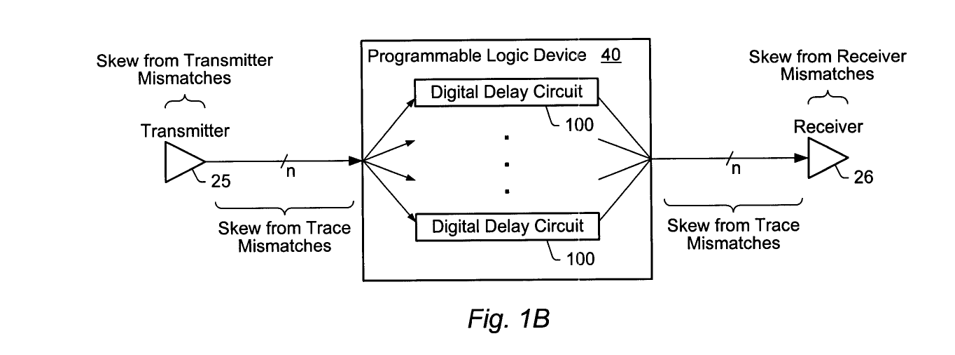

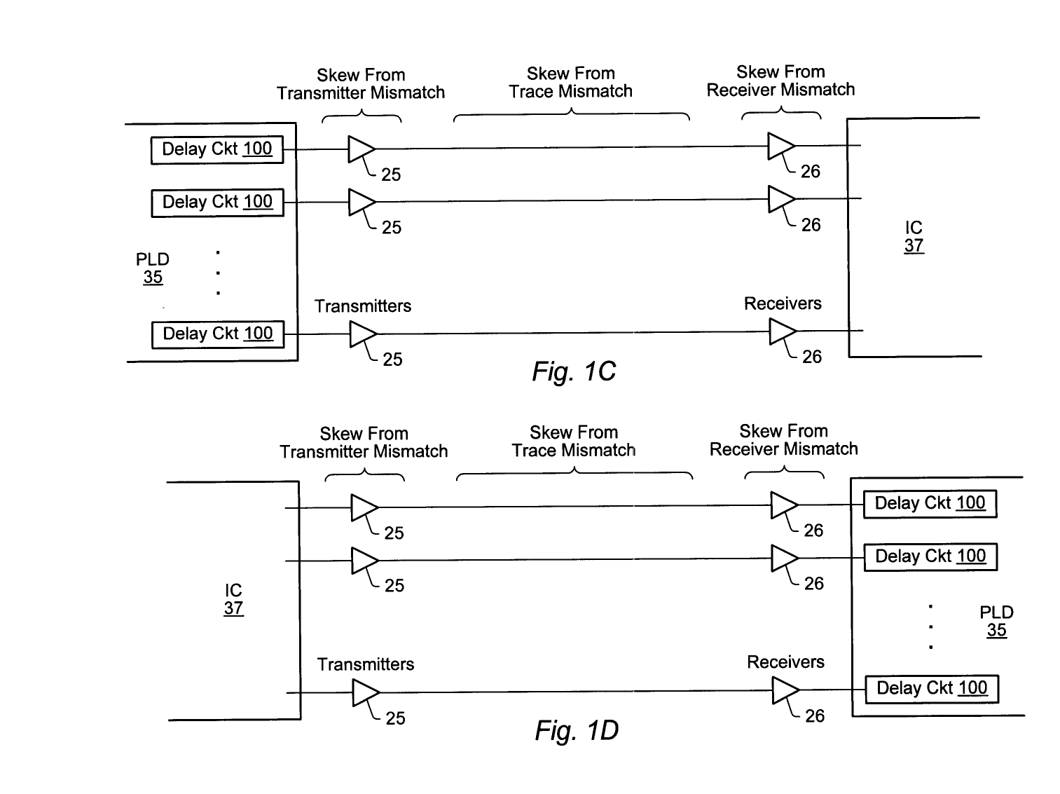

Turning now to FIG. 1A, a block diagram of one embodiment of an exemplary system implementing delay lines using a programmable logic device is shown. System 10 is an exemplary electronic system which includes application specific integrated circuits (ASIC's) 22 and 24, both of which are coupled to field programmable gate array (FPGA) 40. FPGA 40 is a programmable logic device (PLD) that is configured to perform various functions of system 10. Other types of PLD's may be used in lieu of FPGA 40.

Delay circuit 100 is implemented in FPGA 40, and is configured to provide delay to signals being transmitted to ASIC 24, and may be one of a plurality of delay circuit implemented in FPGA 40. Delay circuit 100 may be configured during the programming of FPGA 40. The configuring of delay circuit 100 may be done with several specific objectives in mind.

One objective is to configure delay circuit 100 such that it has a certain resolution, which is the amount of delay per step. As will be discussed below, delay circuit 100 may be implemented using a plurality of delay elements, which may have a large, medium, or small delay. In one embodiment, the resolution is based on the smallest delay provided by a delay element in the circuit. Delay may be measured in various units, such as picoseconds or nanoseconds.

A second objective in configuring delay circuit 100 is to provide sufficient range. The range may be defined by the absolute maximum and minimum amount of delay that delay circuit 100 provides. Typically, the design of a delay circuit may provide a greater range than is necessary, with a minimum delay that is less than the required minimum delay and a maximum delay that is greater than the required maximum delay. This may ensure that variations introduced into the delay circuit for reasons such as process, voltage, and temperature will not cause the range to fall below requirements.

A third objective in configuring delay circuit 100 is to ensure that it is monotonic. A delay circuit that is monotonic will always provide more delay at delay step n+1 than is provided at step n. In other words, the amount of delay increases with each new delay element added into the circuit. Monotonicity is related to linearity, as a delay circuit that is linear will also be monotonic.

A fourth objective in configuring delay circuit 100 is pulse width/duty cycle preservation. Some delay circuits can distort the pulse width/duty cycle of a signal. However, in many systems, preserving the pulse width/duty cycle is important to proper functioning of the circuit. For high-speed digital systems, pulse width/duty cycle preservation may be especially critical in order to ensure proper timing within a specified error margin.

Providing linearity (within a specified error margin) is another objective in configuring delay circuit 100. In one embodiment, linearity (like resolution) is based on the smallest step size. For a given size delay element, linearity may be defined that the delay elements provide a substantially equal amount of delay and thus the amount of delay increases steadily in accordance with the step size as additional delay elements are added into the circuit.

A sixth objective of configuring delay circuit 100 is to prevent unwanted pulses (i.e. “glitch-free) operation. If not compensated for in the design, unwanted pulses may occur when switching between the outputs of the delay elements in delay circuit 100. By compensating the design to account for factors such as race conditions, unwanted pulses may be substantially eliminated from the outputs of delay elements within a delay circuit 100.

After designing and programming FPGA 40 to include one or more delay circuits 100, the delay circuits may be calibrated upon FPGA 40 being implemented into the system (e.g., when FPGA 40 [or other type of PLD] is attached to a printed circuit board) in which it is intended. The delay circuits 100 may also be re-calibrated once in FPGA 40 is implemented into the system if necessary, and a wide variety of calibration mechanisms may be used.

Moving now to FIG. 1B, a block diagram of one embodiment of a circuit implementing a digital delay line is shown. In the embodiment shown, transmitter 25 is coupled to receiver 26 via a bus having multiple signal lines. A delay circuit 100 is interposed on each signal line between transmitter 25 and receiver 26. The bus coupling transmitter 25 and receiver 26 may convey one or more of various types of digital signals, such as address signals, data signals, clock signals, and so forth. Each digital delay circuit 100 may be located within a PLD such as an FPGA. Transmitters 25 and/or receivers 26 may also be located within the PLD in some embodiments while in other embodiments both transmitters 25 and receivers 26 are located external to the PLD.

Each delay circuit 100 is used to compensate for propagation delay variations that may occur between transmitter 25 and receiver 26. Skew may be introduced via propagation delay variations at both transmitter 25 and receiver 26. Furthermore, variations in the signal lines (e.g. different lengths) may also induce variations in propagation delay. Each delay circuit 100 may be able to compensate for the propagation delay variations introduced into the transmission path between transmitter 25 and receiver 26, and may thus ensure that the signals are properly timed. The delay circuits 100 may each be set individually, as the amount of delay required to ensure correct timing may vary with each signal line. Each delay circuit may include large, medium and/or fine delay elements, which will be discussed in further detail below.

FIGS. 1C and 1D are block diagrams illustrating embodiments of circuit implementing digital delay lines. In each figure a PLD 35 includes a plurality of delay circuits 100. As shown in FIG. 1C, the delay circuits 100 may have outputs that are each coupled to a transmitter 25 for transmitting the signals to an integrated circuit (IC) 37. In FIG. 1D, each of the delay circuits 100 is coupled to an output of a receiver 26. Thus, the delay circuits 100 may be placed anywhere in the signal path.

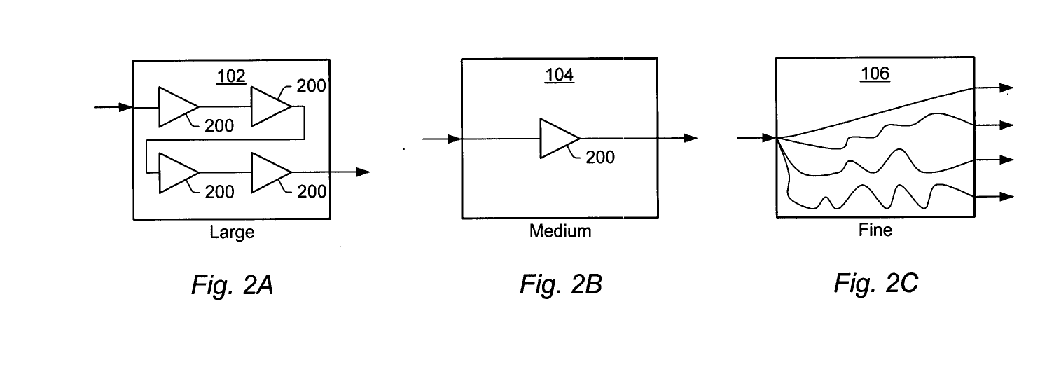

FIG. 2A is a block diagram of one embodiment of a delay element for implementing a large delay. In the embodiment shown, large delay element 102 includes a plurality of logic devices 200. The logic devices may be connected in a serial manner as shown, such that a signal input into large delay element 102 propagates through each of the logic devices. The cumulative propagation delay encountered by a signal passing through each of logic devices 200 provides the delay in this embodiment of large delay element 102.

In one embodiment of large delay element 102, the plurality of logic devices 200 may include both inverting and non-inverting logic devices, such as inverters and non-inverting buffers. For example, the first and third logic devices 200 may be inverters, while the second and fourth logic devices may be non-inverting buffers.

The serial coupling of a plurality of inverting and non-inverting logic devices may help preserve the duty cycle of signals propagating through large delay element 102. This is due to the fact that in many cases, an inverter or a non-inverting buffer (or other inverting/non-inverting logic devices) may have a different propagation delays for rising edges and falling edges of a signal. If left uncompensated, these different propagation delays for rising and falling edges can distort the duty cycle. However, replacing every other non-inverting buffer with an inverter (or other inverting logic device) may substantially negate this distortion of the duty cycle. In one embodiment, large delay element 102 is implemented with an equal number of inverting and non-inverting logic devices. In embodiments of a delay circuit where the number of inverting and non-inverting logic devices are not equal, an extra inverter may be present elsewhere in the circuit in order to provide a balanced number of inverters and non-inverters. Broadly speaking, providing a balanced number of inverting logic elements and non-inverting logic elements may allow for better duty cycle preservation, as the rising and falling edges of signals passing through the delay circuit will propagate with substantially the same amount of delay. This may be especially useful in long chains of logic elements used to construct a delay element or delay circuit where duty cycle distortions become may be more likely to occur.

While some embodiments of large delay element 102 may implement logic devices 200 with inverters and non-inverting buffers, other embodiments may implement logic devices 200 with other logic devices. For example, an inverting logic device may be implemented using a NAND gate with the inputs tied together, while a non-inverting logic device may be implemented using an AND gate with the inputs tied together.

FIG. 2B is a block diagram of one embodiment of a delay element for implementing a medium delay. In the embodiment shown, medium delay element 104 includes a logic device 200, which may be inverting or non-inverting. Medium delay element 104 may include additional logic devices 200 (inverting and/or non-inverting), but in general provides less delay than large delay element 102 discussed above (and thus will have fewer logic devices).

In the case where medium delay element includes only one logic device 200, an additional logic device may be present elsewhere in the delay circuit for the purposes of duty cycle preservation. For example, if medium delay element 104 includes a single inverter, another inverting logic device (e.g. another inverter or an inverting input to a multiplexer) may also be present elsewhere in the circuit.

FIG. 2C is a block diagram of one embodiment of a delay element for implementing a fine delay. In the embodiment shown, fine delay element 106 includes a plurality of traces, wherein each trace is of a different length with respect to the other traces. A trace can be a wire or any other type of signal path. Since each trace has a different length with respect to the other traces of fine delay element 106, signals propagating on the different traces will typically encounter different delay times. However, the amount of delay in any given signal path through fine delay element 106 will be less than the amount of delay through a large delay element 102 or a medium delay element 104.

Since the embodiment of fine delay element 106 shown in FIG. 2C includes multiple signal paths, it also includes multiple outputs. Thus, fine delay element 106 may be coupled to a selection circuit (e.g. a multiplexer), which may select the output associated with the signal path that provides a delay that is closest to the amount desired. Using a selection circuit to select a specific output from fine delay element 106, the overall delay of a delay circuit (in which the fine delay element is included) may be fine-tuned. Thus, the sizes of the individual steps in a fine delay element may determine the overall delay step size for a delay circuit in which it is featured.

It should be noted that while the embodiment of fine delay element 106 shown in FIG. 2C does not include any logic devices, other embodiments are possible and contemplated wherein one or more signal paths include a logic device. Furthermore, fine delay elements having a different configuration than that shown in FIG. 2C are also possible and contemplated. In general, the various possible embodiments of fine delay element 106 may be configured to have a smaller amount of delay than medium delay element 104 or large delay element 102.

While three different delay element sizes have been described above, it should be noted that delay circuits may be implemented in accordance with this disclosure using any number of delay element sizes, and thus are not limited to only the large, medium, or fine delay elements described herein (e.g. a delay circuit having four different sizes of delay elements). It is further noted that delay circuits implemented using only one specific type of delay element (e.g. large delay element 102 described above) are also possible and contemplated.

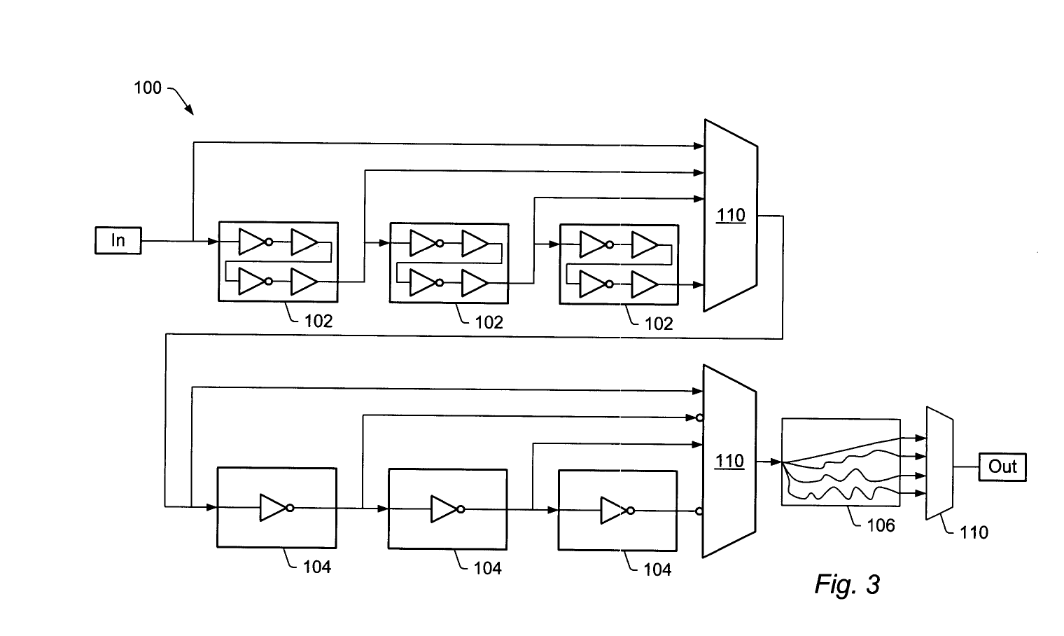

Moving now to FIG. 3, a block diagram of one embodiment of a delay line implemented using large delay elements, medium delay elements, and fine delay elements is shown. In the embodiment shown in FIG. 3, a plurality of large delay elements 102, medium delay elements 104, and a fine delay element 106 are arranged in a cascaded manner to form a delay circuit 100 for a single signal line. A plurality of multiplexers 110 are also provided in order to allow a specific delay value to be set for the circuit.

In this particular example, the input of delay circuit 100 is coupled to a first of three large delay elements 102. The input is also directly coupled to an input of a first multiplexer 110, as are the output of each of large delay elements 102. In addition, the outputs of the first two large delay elements 102 are coupled to the input of the next delay element in the chain. Thus in this embodiment, multiplexer 110 may select a signal that has passed through none of the large delay elements, one of the large delay elements, two of the large delay elements, or all three of the large delay elements. This portion of delay circuit 100 may thus be used for coarse adjustment of the delay the circuit is to provide.

A medium amount of delay adjustment may be provided in this particular embodiment by the plurality of medium delay elements 104 that are cascaded together. The input of the first medium delay element 104 is coupled to the output from the first multiplexer 110. The arrangement of the medium delay elements 104 is the same as the arrangement of the large delay elements for this embodiment, and thus the second multiplexer 110 may select the path through which a signal propagates between the first and second multiplexer outputs. A signal propagating through the delay circuit 100 of FIG. 3 may pass through none, one, two, or all three of the medium delay elements.

In the embodiment shown in FIG. 3, each medium delay element 104 includes a single inverter for providing propagation delay. Thus, the second multiplexer 110 includes inverting inputs coupled to the outputs of the first and third medium delay elements 104 to ensure that the signal propagates through in it's intended state.

The second multiplexer 110 in this embodiment is coupled to convey a signal to fine delay element 106. In the embodiment shown, fine delay element 106 has a single input and plurality of wires, each of different length with respect to the others. Each wire provides a separate signal path to an input of the third multiplexer 110. Thus, the third multiplexer 110 may be used to fine tune the amount of delay provided by delay circuit 100.

Using the combination of large, medium and fine delay elements, the range and resolution of delay circuit 100 may be set. For example, assumed the delay provided by the large delay elements 102 is 4 nanoseconds (ns), the delay provided by the medium delay elements 104 is 1 ns, while the fine delay element 106 provides four delay steps with a step size of 250 picoseconds (ps; 0 ps, 250 ps, 500 ps, and 750 ps). The delay steps that may be provided by the plurality of large delay elements 102 are 0 ns, 4 ns, 8 ns, and 12 ns. The delay steps that may be provided by the plurality of medium delay elements 104 are 0 ns, 1 ns, 2 ns, and 3 ns. Thus, in this particular case, the delay circuit has a range of 15.75 ns, or (3*4 ns)+(3*1 ns)+(3*250 ps). The resolution for this circuit is 250 ps, as it represents the finest amount of delay by which the circuit may be adjusted.

In general, one embodiment of the fine delay circuit 106 may be designed to have X steps of Y ps in length, and thus the total delay span of the fine delay element is X*Y. In this embodiment, the medium delay may be designed such that it is (X+1)*Y ps. Thus, if there are Z medium steps, the span of all medium steps is Z*((X+1)*Y) ps. The large delay steps in this embodiment may be designed to be (Z+1)*((X+1)*Y) ps in length. This trend could also be continued for W extra large delay steps, yielding a range of [(W+1)*(Z+1)*(X+1)*Y]−Y ps. Methods of designing the delay circuits other than those describe here are also possible and contemplated.

While the embodiment described above includes large, medium, and fine delay elements, other embodiments are also possible. For example, delay circuits constructed of only large or only medium delay elements are possible, as are delay circuits that include both large and medium delay elements or fine and medium delay elements.

In some embodiments, the multiplexers shown in FIG. 3 may be hardwired such that a predetermined amount of delay is always provided. Since the delay circuits described herein are implemented in PLDs, the hardwiring may be accomplished during the programming process. In other embodiments, the amount of delay may be selected and changed during the operation of the system in which the PLDs are used. This may allow the delay to vary according to certain operating conditions, and thus yields a more flexible delay circuit. It is also noted that the multiplexers (or selector circuits in general) may be set (or reset) by using calibration tools after the PLD including the delay circuits is implemented within a system. This allows the amount of delay provided by each delay circuit to be changed or calibrated without re-running the design tools. In various embodiments the delay circuits may be changed or calibrated within the system on an individual basis and/or on a system-wide basis. This further allows the delays to be set to specific values, as process, voltage, and temperature variations may not always allow the exact delays of each delay circuit to be known upon completion of the design process.

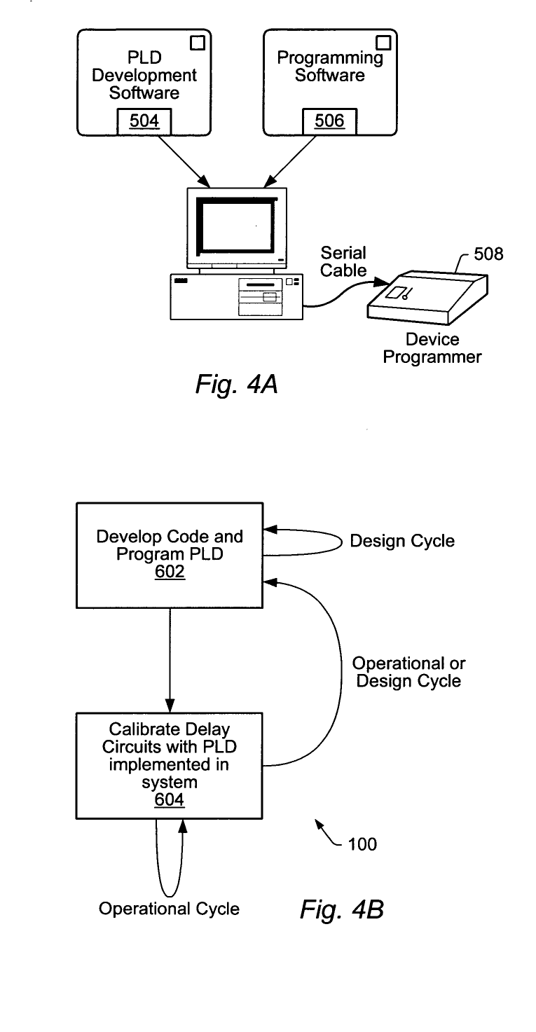

FIG. 4A is a drawing of one embodiment of a system used to program a PLD, wherein programming the PLD includes implementing delay circuits. Other programming systems are possible and contemplated, and in general, any system suitable for programming PLD's may be used to implement the various embodiments of the delay circuits discussed herein.

In the embodiment shown, programming system 500 includes computer 502, which is configured to execute instructions from PLD development software 504 and programming software 506. The development software 504 in this embodiment is configured to translate the input design into a physical design layout for the actual PLD. The programming software provides communications between computer 502 and fixture 508. In the embodiment shown, fixture 508 includes a zero-insertion force (ZIF) socket configured to receive a PLD. Signals are provided to the PLD through fixture 508 during the process of configuring the PLD circuitry.

The PLD software 504 may include an editor that allows for handwritten code. Using the editor, various operational characteristics (e.g. timing) of the circuits may be specified. PLD software 504 may also allow for the creation of macros, which may have various uses. For example, macros may include specific routing information, and thus may be used to adjust the delay of a metal trace, which is particularly useful in designing embodiments of the fine delay elements discussed above.

Moving now to FIG. 4B, a flow diagram of one embodiment of a method in which the delay circuits may be configured to provide a specified amount of delay is shown. Method 600 includes the development of code and subsequent programming of a programmable logic device (602). The code development and PLD programming may occur on a system such as that illustrated in FIG. 4A or other type of suitable development system. The development and programming of the PLD may include both the designing of delay circuits to be implemented within the PLD as well as any other functions that the PLD may provide. Once the design cycle is complete, the programming may configure the circuits of the PLD, including the initial configuring of the delay circuits.

Following the programming of a specific part, it may be placed into its intended system and calibrated (604). Since, in some embodiments, the exact amount of delay provided by the delay circuits is not known upon completion of initial configuration, a calibration routine may set the delay to a specific value. The calibration routine may include, in one embodiment, sending signals through the delay circuits and performing a measurement of the delay encountered. Based on the measured delay, the selection circuits in each delay circuit may be used to adjust the amount of delay. The process may be repeated until the delay is at or close to the desired amount. A wide variety of mechanisms, both software and hardware oriented may be used to perform the calibration process, which may be performed manually or automatically. For example, a microprocessor in one embodiment of a system having PLD-based delay circuits may automatically execute a calibration routine upon detecting the presence of the PLD. During the operational cycle, the calibration process may be repeated as necessary. As also noted above, the delay of the delay circuits may be changed to allow for varying operating conditions. No intervention by the design tools is required for calibrating the delay circuits.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

1. A delay circuit comprising:
a plurality of delay elements, wherein the delay elements are implemented in a programmable logic device (PLD), wherein the plurality of delay elements comprise a balanced number of logic elements such that rising and falling edges of a signal passing through the delay circuit propagate with substantially the same amount of delay; and
a selector circuit, wherein the selector circuit is coupled to select an output from one of the plurality of delay elements.

2. The delay circuit as recited in claim 1, wherein the delay circuit includes at least one inverting logic element and at least one non-inverting logic element.

3. The delay circuit as recited in claim 2, wherein at least one inverting logic element is an inverter and at least one non-inverting logic element is a buffer.

4. The delay circuit as recited in claim 1, wherein the plurality of delay elements are cascaded together.

5. The delay circuit as recited in claim 4, wherein the plurality of delay elements includes one or more large delay elements, one or more medium delay elements, and one or more fine delay elements.

6. The delay circuit as recited in claim 1, wherein the plurality of delay elements includes one or more large delay elements.

7. The delay circuit as recited in claim 6, wherein each of the one or more large delay elements includes at least one inverter and at least one buffer.

8. The delay circuit as recited in claim 6, wherein the delay circuit is configured to provide a plurality of large delay steps, wherein the size of each of the large delay steps is substantially equal.

9. The delay line circuit as recited in claim 1, wherein the plurality of delay elements includes one or more medium delay elements.

10. The delay circuit as recited in claim 9, wherein the delay circuit is configured to provide a plurality of medium delay steps, wherein the size of each of the plurality of medium delay steps is substantially equal.

11. The delay circuit as recited in claim 9, wherein each of the one or more medium delay elements includes at least one buffer.

12. The delay circuit as recited in claim 1, wherein the plurality of delay elements includes one or more fine delay elements.

13. The delay circuit as recited in claim 12, wherein the one or more fine delay elements includes a plurality of traces, wherein each of the plurality of traces has a different length with respect to the other ones of the plurality of traces.

14. The delay circuit as recited in claim 12, wherein the delay circuit is configured to provide a plurality of fine delay steps, wherein each fine delay step provides a different amount of delay with respect to the other fine delay steps.

15. The delay circuit as recited in claim 1, wherein the delay circuit is configured to provide a plurality of delay steps, wherein the size of each of the plurality of delay steps is substantially equal.

16. The delay circuit as recited in claim 15, wherein an amount of delay provided by the delay circuit at delay step n+1 is greater than an amount of delay provided by the delay circuit at delay step n.

17. The delay circuit as recited in claim 1, wherein a pulse width of a signal input into the delay circuit is substantially preserved when the signal is output from the delay circuit.

18. The delay circuit as recited in claim 1, wherein the PLD is a field programmable gate array (FPGA).

19. The delay circuit as recited in claim 1, wherein the inverting logic element is an inverter and the non-inverting logic element is a buffer.

20. A method for implementing a delay circuit, the method comprising:
programming a programmable logic device (PLD) to include a plurality of delay elements, wherein the delay elements are implemented in a programmable logic device (PLD), wherein the plurality of delay elements includes a balanced number of logic elements such that rising and falling edges of a signal pass through the delay circuit propagate with substantially the same amount of delay, and a selector circuit, wherein the selector circuit is coupled to select an output from one of the plurality of delay elements.

21. The method as recited in claim 20 wherein the delay circuit includes at least one inverting logic element and a non-inverting logic element.

22. The method as recited in claim 21, wherein at least one inverting logic element is an inverter, and wherein at least one non-inverting logic element is a buffer.

23. The method as recited in claim 20 further comprising programming the PLD such that the plurality of delay elements are cascaded together.

24. The method as recited in claim 23, wherein the plurality of delay elements includes one or more large delay elements, one or more medium delay elements, and one or more fine delay elements.

25. The method as recited in claim 23, further comprising programming the PLD such that the plurality of delay elements includes one or more large delay elements.

26. The method as recited in claim 25, wherein each of the one or more large delay elements includes at least one inverter and at least one buffer.

27. The method as recited in claim 25 further comprising programming the PLD such that the delay circuit provides a plurality of large delay steps, wherein the size of each of the large delay steps is substantially equal.

28. The method as recited in claim 23 further comprising programming the PLD such that the plurality of delay elements includes one or more medium delay elements.

29. The method as recited in claim 24 further comprising programming the PLD such that the delay circuit provides a plurality of medium delay steps, wherein the size of each of the plurality of medium delay steps is substantially equal.

30. The method as recited in claim 24, wherein each of the one or more medium delay elements includes at least one buffer.

31. The method as recited in claim 20 further comprising programming the PLD such that the plurality of delay elements includes one or more fine delay elements.

32. The method as recited in claim 31 further comprising programming the PLD such that each of the one or more fine delay elements includes a plurality of traces, wherein each of the plurality of traces has a different length with respect to other ones of the plurality of traces.

33. The method as recited in claim 31 further comprising programming the PLD such that the delay circuit provides a plurality of fine delay steps, wherein each fine delay step provides a different amount of delay with respect to the other fine delay steps.

34. The method as recited in claim 23, further comprising programming the PLD such that the delay circuit provides a plurality of delay steps, wherein the size of each of the delay steps is substantially equal.

35. The method as recited in claim 34, further comprising programming the PLD such that the amount of delay provided by the delay circuit at delay step n+1 is greater than the amount of delay provided by the delay circuit at delay step n.

36. The method as recited in claim 20, wherein a pulse width of a signal input into the delay circuit is substantially preserved when the signal is output from the delay circuit.

37. The method as recited in claim 20, wherein the PLD is a field programmable gate array (FPGA).

38. A method for calibrating a delay circuit, wherein the delay circuit is implemented in a programmable logic device, the method comprising:
selecting the delay of a delay circuit having a plurality of delay elements, wherein the delay circuit is implemented in a programmable logic device (PLD), wherein the plurality of delay elements includes a balanced number of logic elements such that rising and falling edges of a signal passing through the delay circuit propagate with substantially the same amount of delay, and a selector circuit, wherein the delay circuit further includes a selector circuit coupled to select an output from one of the plurality of delay elements, and wherein the PLD is implemented in an electronic system.

39. The method as recited in claim 38, wherein the delay circuit includes a plurality of delay elements cascaded together.

40. The method as recited in claim 39, wherein the plurality of delay elements includes one or more large delay elements, one or more medium delay elements, and one or more fine delay elements.

41. The method as recited in claim 38, wherein the plurality of delay elements includes one or more large delay elements having at least one inverter and at least one non-inverting buffer.

42. The method as recited in claim 38, wherein the plurality of delay elements includes one or more medium delay elements each including at least one buffer.

43. The method as recited in claim 38, wherein the plurality of delay elements includes one or more fine delay elements each having a plurality of traces, wherein each of the plurality of traces has a different length with respect to other ones of the plurality of traces.

44. The method as recited in claim 38, wherein an amount of delay provided by the delay circuit at delay step n+1 is greater than an amount of delay provided by the delay circuit at step n.
